(19) United States
(12) Patent Application Publication
(10) Pub. No.: US 2016/0094016 A1
(43) Pub. Date: Mar. 31, 2016

(54) INCREASING THE SPATIAL AND SPECTRAL BRIGHTNESS OF LASER DIODE ARRAYS

(71) Applicant: Lawrence Livermore National Security, LLC, Livermore, CA (US)

(72) Inventors: Raymond J. Beach, Livermore, CA (US); Robert J. Deri, Pleasanton, CA (US); Michael A. Johnson, Pleasanton, CA (US); Jeffrey L. Klingmann, Livermore, CA (US); William A. Molander, Livermore, CA (US); Mark D. Rotter, San Ramon, CA (US); Michael Runkel, Livermore, CA (US); Craig Siders, Livermore, CA (US); Sheldon S. Wu, Pleasanton, CA (US)

(73) Assignee: Lawrence Livermore National Security, LLC, Livermore, CA (US)

(21) Appl. No.: 14/502,850

(22) Filed: Sep. 30, 2014

(51) Int. Cl. H01S 5/40; G02B 27/30; H01S 5/068; G02B 27/42; G02B 27/46; H01S 5/065; H01S 5/00; G02B 27/14

(52) U.S. Cl. CPC H01S 5/4012; H01S 5/005; G02B 27/30; G02B 27/141; G02B 27/4233; G02B 27/4244; G02B 27/46; H01S 5/0657; H01S 5/06821; G02B 3/0006

(57) ABSTRACT

Techniques for increasing the spatial and spectral brightness of laser arrays such as laser diode arrays are provided. Passive cavity designs are described that produce wavefront phase locking across the face of large arrays. These designs enable both spatial and spectral selectivity in order to coherently link the individual emitters that make up the diode array. Arrays of customized micro-optics correct aberrations of the individual apertures of the arrays while highly spectrally selective partial reflectors overcome the deleterious effects of inhomogeneities in local thermal environments of the individual emitters that are being phase locked together. Using these two technologies, along with intracavity diffractive beam coupling, solves two long standing problems that have prevented effective and robust phase locking of laser diode arrays.

### STATEMENT REGARDING FEDERALLY SPONSORED RESEARCH OR DEVELOPMENT

The United States Government has rights in this invention pursuant to Contract No. DE-AC52-07NA27344 between the U.S. Department of Energy and Lawrence Livermore National Security, LLC, for the operation of Lawrence Livermore National Laboratory.

### BACKGROUND OF THE INVENTION

1. Field of the Invention

The present invention relates to laser diode arrays, and more specifically, it relates to techniques for wavefront phase locking across the face of large laser diode arrays.

2. Description of Related Art

The technology of high-power laser diode arrays used as laser pump sources has advanced in the last 25 years far beyond that of the flash lamp. Today these advancements, particularly the high efficiency and ruggedness of diode arrays, have enabled development in a wide range of areas including medical lasers, materials processing and directed energy. During this time Lawrence Livermore National Laboratory (LLNL) has led technology development of microchannel cooling, which enabled large diode arrays, and integrated optical conditioning, which enabled optical pumping with higher irradiance. This LLNL work has resulted in new applications for direct diodes as well as new classes of average-power lasers, including the ground-state-depleted laser and more recently the diode-pumped alkali laser.

### SUMMARY OF THE INVENTION

High spatial and spectral radiance are key properties of laser diode arrays—properties of which LLNL has understood and taken advantage. The present invention furthers the spatial and spectral radiance of diode arrays via passive cavity designs that cause wavefront phase locking across the face of large arrays. This invention relies on techniques that are both spatially and spectrally selective in order to coherently link the individual emitters (or facets) that make up the diode array.

Inducing coherence among otherwise independent apertures is a well-recognized technique for increasing laser radiance. For applications that require high radiance, the potential simplicity of a phase-locked direct diode array is very attractive compared to the complexity of a system such as a diode-pumped solid-state laser. Specifically, this invention takes advantage of advancements made in the last five years in optical conditioning packages for diode arrays in two specific areas: (1) arrays of customized micro-optics that are now available to correct aberrations of the individual apertures of large diode arrays, and (2) highly spectrally selective partial reflectors that are now available and enable the deleterious effects of inhomogeneities in local thermal environments of the individual emitters that are being phase locked together to be overcome.

Exemplary uses of the present invention include defense applications, illuminator applications, power-beaming applications, material processing and machining applications such as cutting, welding, and surface treatment/modification, medical applications, scientific applications, and pump excitation of diode-pumped solid state lasers and diode-pumped alkali lasers.

The advantages of phase locking diode arrays were recognized early in their development and various approaches have been pursued for many years, but with only very limited success. Particularly in the late 1980s and early 1990s, the U.S. government funded a very aggressive campaign to phase lock large diode arrays for space-based applications. For a variety of technical reasons these phase-locking pursuits were largely unsuccessful. Near the end of this campaign, general opinion held that the phase locking of large 2-D arrays was not adequately developed. Then by the mid-1990s, the high power laser community had shifted its focus to solid-state lasers pumped by incoherent diode arrays—a situation that still dominates defense-oriented government investment.

For the last 25 years, conventional wisdom has advocated using the solid-state laser as a brightness converter—using low-radiance light from large 2-D diode arrays to pump the higher radiance solid-state laser. In contrast, this invention reevaluates several of the early phase locking approaches in light of recent progress in optical technologies applied to diode lasers; particularly the optical conditioning techniques that we have used on the diode arrays for high irradiance pump-excitation of diode-pumped lasers.

This invention is motivated by the need for robust techniques for phasing across diode array apertures. Such techniques are important to enable direct diode arrays to access applications that today require higher spatial radiance (or brightness) sources than available from incoherent arrays and from higher radiance sources such as diode-pumped solid state lasers that, from a system level, involve considerably more complexity and complication than could be realized with direct phase-locked diode arrays.

### BRIEF DESCRIPTION OF THE DRAWINGS

The accompanying drawings, which are incorporated into and form a part of the disclosure, illustrate embodiments of the invention and, together with the description, serve to explain the principles of the invention.

FIGS. 1A-IC show side views of a diode bar with its output being collimated by a fast-axis lens and then retro-reflected back to the array.

FIG. 1D shows the basic elements of the means for optically conditioning the output of a laser diode bar and includes a fast axis collimating lens, a slow axis collimating optic and an advanced optic.

FIG. 2 is a schematic diagram of an embodiment of the present invention using a cavity with a complex spatial filter for phase locking a single diode bar in the slow-axis dimension.

FIG. 3A shows the white areas in the black screen of the shaped aperture of FIG. 2 representing areas of maximal transmission.

FIG. 3B shows a magnified view of the rectangular area in FIG. 3A indicated by the dashed white outline with a lineout of the diode irradiance along the horizontal axis of the mask (in arbitrary units).

FIG. 4 illustrates the present invention applied to a 2-D diode array consisting of 6 unit cells in a 2×3 arrangement, each unit cell consisting of 20, 1 cm long diode bars.

FIG. 5 is a schematic diagram of the present invention using a Talbot cavity for 2-D diode array phase locking.

FIG. 6 shows the Talbot cavity of FIG. 5 but with a follow on pair of corrector plates after the VBG retro reflector.

### DETAILED DESCRIPTION OF THE INVENTION

This invention enables phase locking via the diffractive coupling of the individual facets on the laser diode bars, which are themselves stacked in two-dimensional arrays. High-average-power diode arrays, as they are used today, usually consist of diode bars that have 10 to 25 independent broad area facets spaced along the length of each bar, with individual facets emitting incoherently with respect to one another.

In recent years robust and reliable phase locking demonstrations have been hindered by two specific problems which can now be addressed with commercially available technologies. The focus of this invention is the recognition that with appropriately designed laser cavities that incorporate these two technologies, these existing problems can be mitigated and robust and reliable phase locked arrays realized.

The first issue is commonly referred to as the “smile” problem, which is caused by a slight bend in the nominally straight pattern of emitters on a diode bar. This bend is typically a result of imperfections in either the sub-mount flatness or in the uniformity of the solder layer attaching the bar to the sub mount, or both. Most proposed optically implemented phase locking schemes rely on fast-axis pointing accuracy being maintained from emitter to emitter, but the smile error causes emitter-to-emitter variation in fast-axis pointing accuracy after the light passes through the monolithic fast-axis collimating lens.

The solution to this problem is an advanced beam conditioning optic, often referred to as an advanced optic (AO), which is custom fabricated for a given diode array in order to correct for the smile errors that are specific to that array, thereby restoring pointing accuracy to the fast-axis radiation. AO's are designed by first diagnosing the smile error across individual diode bars after having their output conditioned by a FAC and SAC microlens. Using a wavefront sensing method to obtain the local tilt in the wavefront across a diode array, the AO's are designed to compensate for the local tilt error through a refractive correction. The AO's themselves are then fabricated in fused silica or other transparent substrate material using a direct write laser micro-machining process via a focused CO₂ laser beam that is rastered across the surface to be machined. Machined microplates are then aligned to the operating diode bar using a micro-positioning stage, and finally fixed in place using a UV-cured glue. For a more detailed explanation see: J. F. Monjardin, K. M. Nowak, H. J. Baker, and D. R. Hall, “Correction of beam errors in high power laser diode bars and stacks,”/4 Sep. 2006/Vol. 14, No. 18/OPTICS EXPRESS 8178.

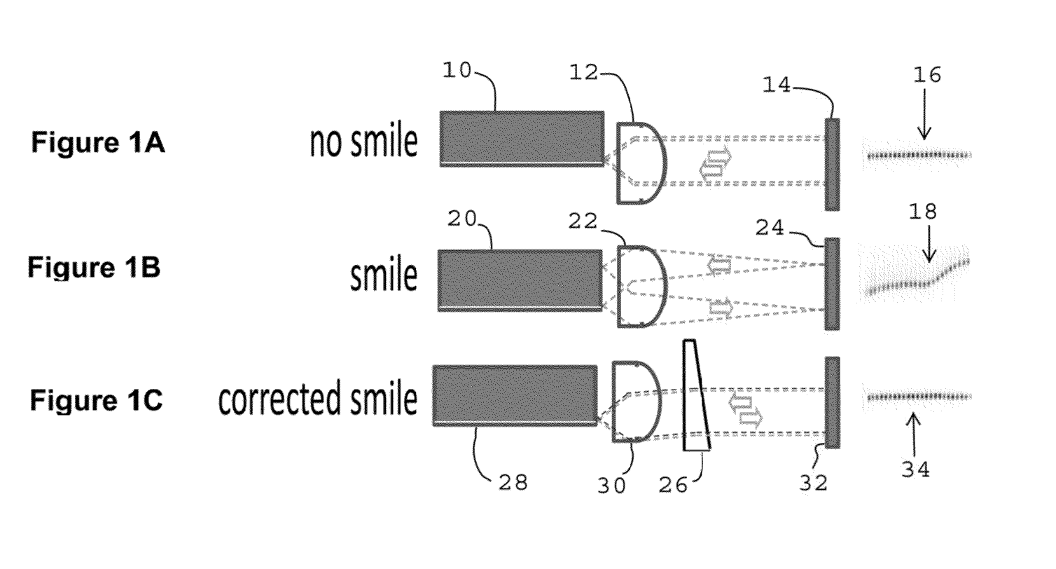

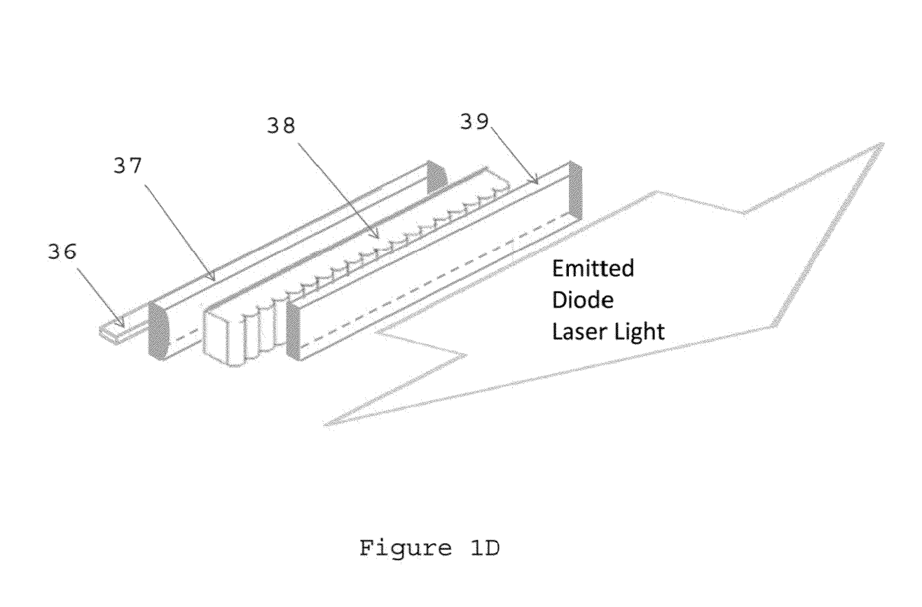

FIGS. 1A-1C show three side views of a diode bar with its output being collimated by a fast-axis lens and then retro-reflected back to the array. FIG. 1A shows a side view of diode facets when they are properly aligned to the axis of the microlens. FIG. 113B shows diode facets that are not properly aligned to the axis of the microlens (due to smile). FIG. 1C shows improperly aligned diode facets as in FIG. 1B but this time with an optical corrector which functions to refractively correct the radiation after the fast-axis lens.

More specifically, FIG. 1A shows a side view of a laser diode array 10. The diode array has a series of individual laser facets (emitters). In this case, it is assumed that all of the facets are aligned in a straight line that is perpendicular to the page. When all of the facets are properly aligned to cylindrical fast-axis microlens 12, the radiation after the lens on retro-reflection by partial reflector 14 is returned back to the laser diode emitter from which it was emitted. The straight line of outputs 16 from the laser diode array would be viewed on a plane parallel with the facets (emitters). Smile errors, illustrated as reference number 18 in FIG. 1B, are caused by the misalignment of the emitters on diode bar 20 with respect to the microlens 22 in the direction perpendicular to the plane of the page such that the laser diode emitters are not all aligned on the optic axis of the microlens. Therefore the collimated light emerging from the lens propagates at an angle to the optical axis of the lens and, on retro reflection by partial reflector 24, is not returned to its point of origin. That is, the emitters are misaligned for the purposes of this proposed phase locking scheme. FIG. 1C shows refractive optic plate 26 positioned at an appropriate angular correction to the beam to correct for the fast-axis error in FIG. 1B. In this case, even though the emitters of diode bar 28 are misaligned to the microlens 30, the retro-reflected light from partial reflector 32 is successfully returned to the facet from which it emerged such that the output beams 34, as they would be viewed in a plane parallel to the output facets, are aligned such that no smile error is present. Today such custom corrector plates are commercially fabricated to correct an entire diode bar—or even a 2-D array—on an individual diode basis. This invention for the phase-locking of diode arrays using a passive external cavity depends on accurate correction of such “smile” errors. FIG. 1D shows the basic elements of the means for optically conditioning the output of the laser diode bar 36 and includes a fast axis collimating lens (FAC) 37, a slow axis collimating (SAC) optic 38 and an advanced optic (AO) 39.

Fast-axis collimating lenses are widely available commercially, for example LIMO Lissotschenko Mikrooptik GmbH offers a complete line of microlenses appropriate for conditioning the fast-axis and slow-axis radiation of laser diode arrays. Although the AO corrector plates are a somewhat newer technology than are microlenses, such AO plates are now available commercially from PowerPhotonic Ltd. in the United Kingdom, which offers customized AO plates as a catalogue item.

The second issue that has been limiting phase locking is the tendency of the independent laser emitters to operate at slightly different center wavelengths. This wavelength variation is caused primarily by emitter-to-emitter differences in the local thermal environments. The solution to this problem is the use of an external resonant reflector for the diodes—a reflector in the form of a shallow Bragg grating fabricated in photosensitive glass. In essence, such resonant reflectors feedback only a single wavelength into the diode cavity, thereby overwhelming the small wavelength differences among emitters in their peak gain as long as the temperature excursions are not too large. Such resonant reflectors are commonly referred to as VBGs (volume Bragg gratings) and along a single diode bar can limit the bandwidth of emitted light to several tenths of a nanometer or less. As discussed above, the means provided by the present invention for the correction of the smile problem improves phase locking of laser diode arrays. Phase-locking of laser diode arrays is further improved by the present invention through the correction of local thermal inhomogeneities in large arrays. We note that alternate means, such as a reflection grating, may be used for correcting the wavelength variation of the emitters. Similar optical means for narrowing the line width will be apparent to those skilled in the art based on the teachings of the present invention, and such alternate means are within the scope of the invention.

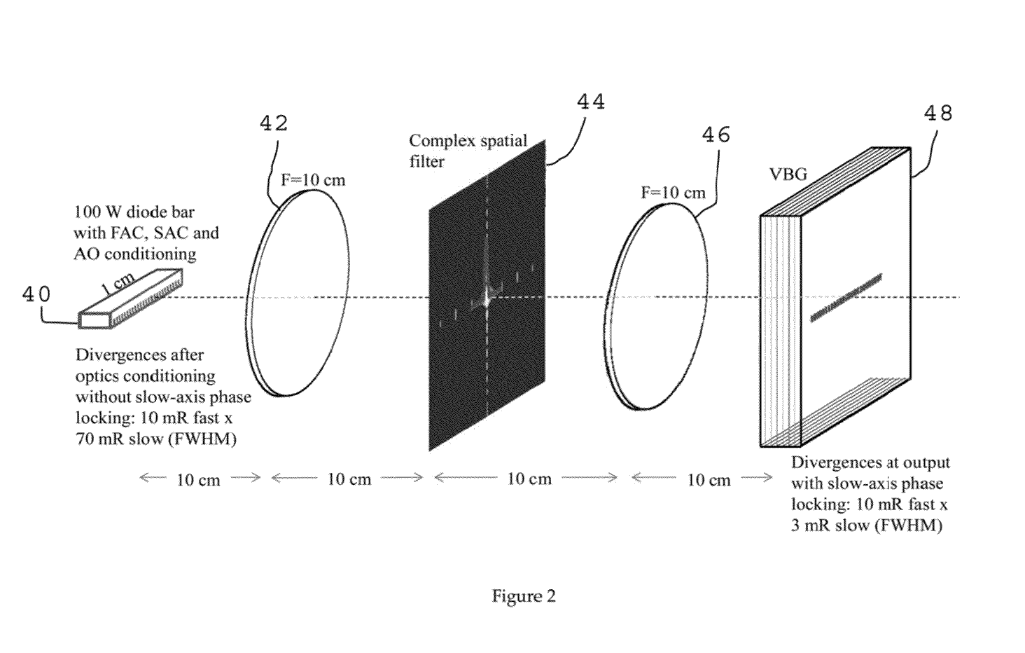

Both of these technologies have been demonstrated and matured at the bar level in incoherently emitting diode arrays, and in fact are incorporated into the diode pump arrays used for existing laser systems such as the LLNL diode-pumped alkali laser system. This invention extends these same technologies in an optical design that establishes coherence among the individual facets in the array. To do this, as illustrated in FIG. 2, we use a 1-D diode array with low reflectivity coatings on its output facets and including an optical conditioning package composed of fast-axis collimating lenses (FAC), slow-axis collimating lenses (SAC), and an advanced optic (AO) to correct for smile errors in individual bars. Then using an external cavity we close the laser resonator using a spectrally selective mirror in the form of a continuous VBG that covers the entire aperture of the array. Several techniques for promoting the intracavity diffractive coupling from diode aperture to diode aperture as required for phase locking are possible, and we utilize two specific ones based on either an intracavity complex spatial filter or a Talbot plane coupling scheme for this invention as discussed next.

The first variation of this invention uses an intracavity complex spatial filter. The use of intracavity spatial filters to phase lock individual diode gain elements has already been demonstrated. More recently the benefits of an intracavity spatial filter to substantially improve beam quality from an individual broad area laser diode emitter has been shown. Such a filter limits the spatial and temporal instabilities in diodes that otherwise lead to transverse mode broadening.

More specifically, FIG. 2 shows a schematic diagram of an exemplary embodiment of the present invention using a cavity with a complex spatial filter for phase locking a single diode bar in the slow-axis dimension. The output facet, with individual laser diode emitters, of a laser diode bar 40, are conditioned by optics such as shown in FIG. 1D, and is placed at the focal plane of a first lens 42 such that the collimated output of the slow axis lens is focused at the focal plane of first lens 42. A complex spatial filter 44 is placed at the focal plane of lens 42 and is followed by a collimating lens 46. A VBG 48 is placed after lens 46. The laser diode bar is selected to provide 100 watts and includes a FAC, a SAC and AO conditioning. The divergence after the AO conditioning without slow-axis phase locking is 10 mR (FWHM) for the fast axis and 70 mR (FWHM) for the slow axis. Lenses 42 and 46 both have F=10 cm and are placed 20 cm apart. The complex spatial filter 44 is placed at the midplane between the two lenses. The divergences at the output of the VBG 48 with slow axis phase locking are 10 mR (FWHM) for the fast axis and 3 mR (FWHM) for the slow axis. So the effect of the phase locking apparatus shown to the right of the diode bar in FIG. 2 is to narrow the divergence of the emitted slow-axis radiation from the 70 mRad that characterizes a bare diode bar to 3 mR when phase locked.

Thus, this invention extends beyond previous works by introducing a specialized complex spatial filter, and using the optical conditioning of the diode array and the spectrally selective VBG reflector as described above. FIG. 2 has shown this invention applied to a single bar. The complex spatial filter aperture spatially filters the diode radiation passing through the cavity at the filter location. By choosing the pass band of the VBG to be less than the natural linewidth of the emitted radiation from the diode bar if it were operating without a VBG, we can limit the bandwidth of the resonated radiation and effectively improve the control of the macroscopic mode of the entire diode bar and therefore improve the degree to which we can phase lock its emission.

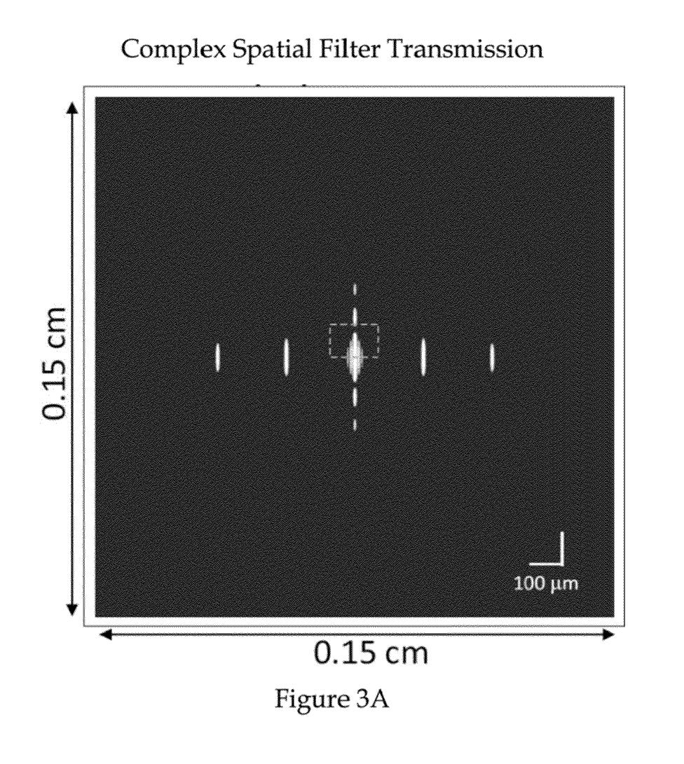

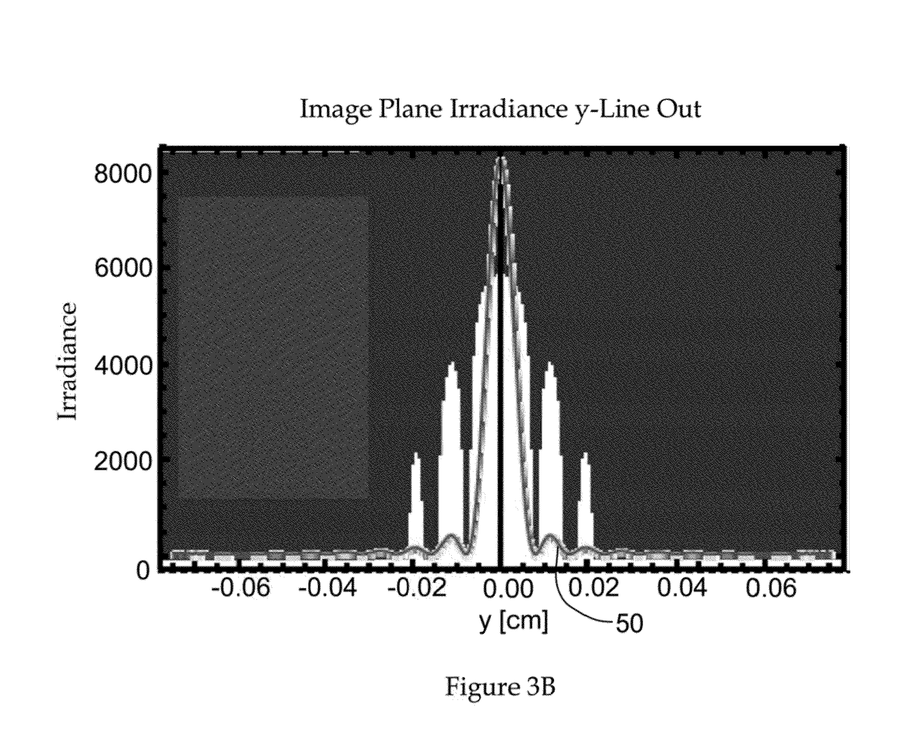

As a specific example of this invention consider FIG. 2 in which the system is running in the so called “in-phase” mode in which the phase at each aperture of the diode bar is identical. In many respects this is the preferred mode in which to run the laser bar because this mode will give the smallest possible far-field spot. FIG. 3A shows the aperture shape appropriate for this mode. The aperture is designed with high transmission at locations in the transform plane only where the irradiance from the “in phase” mode of the diode bar is greater than the threshold value of 1% of the peak irradiance in that plane. There is no transmission elsewhere. Depending on the detailed requirements of the system's output radiation the use of the 1% threshold point may be changed to a different value. FIG. 3B shows a magnified view of the dashed area of FIG. 3A. FIG. 3B includes a lineout 50 of the laser irradiance along the horizontal axis of the filter of FIG. 3A.

One of the challenging technology areas associated with this invention is the fabrication of the contoured complex spatial filter mask. Another issue with the complex spatial filter masks is the management of high-power light that strikes the mask at locations where it is not intended, a situation requiring aggressive thermal management at those locations. To this end, we identify three well known and well developed fabrication options for the spatial filter masks and list the strengths and weaknesses associated with each option.

1. Silicon etching—this process is done by creating a mask then exposing resist on a silicon wafer. Small features can be made to very good repeatability but not absolute accuracy so a fabricate-measure-re-fabricate process would have to be invoked, which complicates the fabrication process. The strength of this process is the ability to make many copies of a design. Typical silicon wafers are 0.5 to 0.75 mm thick but the area around the mask features could be back-thinned to whatever degree is required. For removing heat from the mask, silicon has ˜150 W/m-K conductivity, so depending on the degree of heat to be removed, this may work sufficiently well. For more aggressive thermal management, a heat exchanger could be etched into the wafer using the same silicon based microchannel approach as used for silicon submounts for high power laser diode arrays.

2. Laser cutting—this process can achieve the desired accuracy, especially by feeding back accurate metrology of the feature size and location. This feedback iteration can be quick as the laser cut is guided by a computer program—a flexible process. There are different options for laser wavelength and these result in different edge quality on different materials. There are several different design options using laser cutting as the material removal process:

a. Molybdenum sheet—Moly is an attractive material in that it has moderately high thermal conductivity at 140 W/m-K, is available in sheet stock to even a few micron thickness and can withstand high temperatures. For significant heat loading on the mask, the foil will have to be thermally sunk to a heat sink. If the heat sink is copper, bonding isn't trivial with soldering/brazing but a thermally conductive epoxy could be used without too much thermal resistance at the joint.

b. A solid copper substrate can be used thereby allowing a monolithic structure. The copper block would be thinned in the area of the optical mask and heat transfer fins and fluid paths machined directly in the copper.

c. Silicon Carbide (SiC) is another advantageous material. For temperatures below about 500° C., its thermal conductivity is higher than that of Moly and approaches that of Copper at room temperature. In addition, SiC is more of a volumetric absorber of light. This leads to a smaller temperature rise (as compared to a surface absorber) for a given amount of power incident on the material.

3. Deposition methods—The mask can be made from a transparent material that then has an opaque material deposited on it to form the mask. Using a high thermal conductivity material such as CVD diamond for the transparent substrate would allow efficient transport of the heat away from absorbing mask locations.

At the level of accuracy required for these masks, two-dimensional metrology to a few microns (3-5 microns) is within the commercial product sector which uses tools that routinely work at this level.

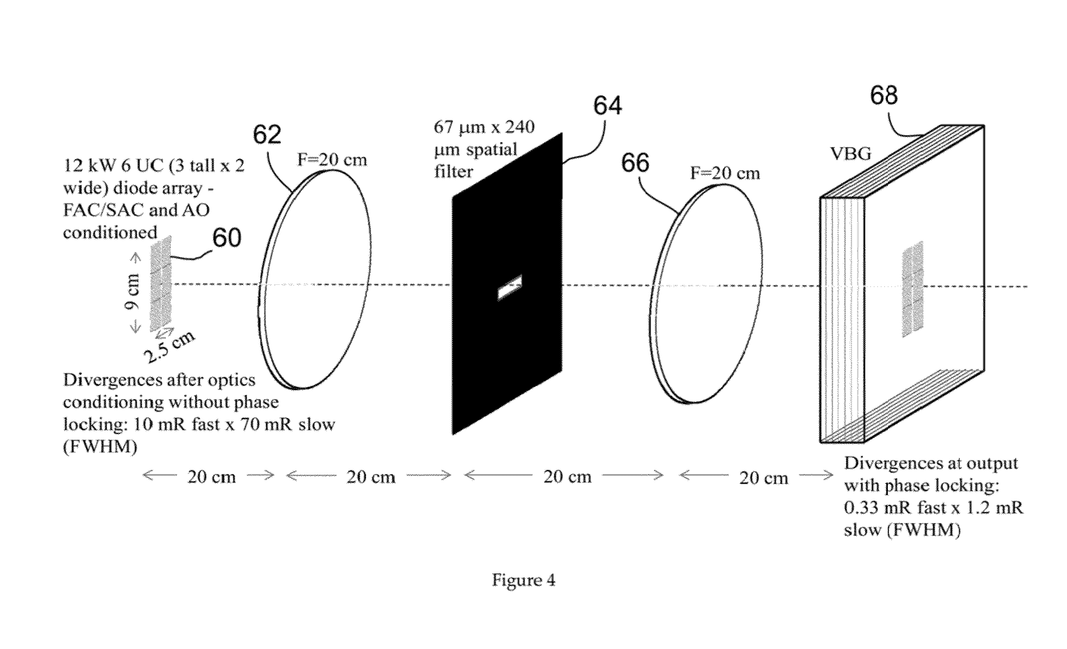

This invention is also directly applicable to 2-D arrays. This is illustrated in FIG. 4 where the essential features of this invention are expanded to a 2-D array. An interesting feature of the spatial filter shown in FIG. 4 is its simple rectangular shape compared to the complicated spatial pattern that would be appropriate for single-mode operation of the 2-D array.

More specifically, FIG. 4 shows a 2-D diode array 60 placed on the focal plane of a collimating lens 62. A spatial filter 64 is placed between lens 62 and focusing lens 66. VBG 68 is placed at the focal plane of lens 66. The 2-D diode array 60 consists of 6 unit cells in a 2×3 arrangement, each unit cell consisting of 20, 1 cm long diode bars. Other specifications for the elements of this embodiment are stated directly on the figure. This diode array can source approximately 12 kW at its emitting surface at 100 W/bar. The rectangular opening in the spatial filter 64 represents an angular pass band of 0.33 mR in the fast (or vertical) dimension and 1.2 mR in the slow (or horizontal) dimension. If we were to anamorphically relay the output of this cavity to a 30-cm-diameter beam director, the beam director output would have a divergence angle of 0.1 mR, corresponding to a 100-m spot at a 1000 km throw.

The reason for the simpler rectangular aperture in this case is that we are not attempting to restrict the laser cavity to the single “in phase” mode as we did for the single-bar setup in FIG. 2, but rather by design we are allowing multiple modes to be transmitted through the aperture. Even though the array will operate in many transverse modes in this case, we are still severely restricting the number of modes that can lase relative to those supported by the bare array itself. For the specific configuration shown, radiation emerging from this cavity will be ˜40 times diffraction limited (TDL) in each dimension, which in very rough terms can be restated as saying that there are about 40²=1600 transverse modes lasing in the cavity. Allowing operation over a large number of multiple transverse modes gives larger spot diameters in the far field but can also drive down local intensity variations, which in many applications is an important consideration.

This flexibility to shape the aperture in the complex spatial filter enables the optimization of the properties of the output beam of the system for a particular work piece or target. We view this freedom in particular as an attractive feature of this invention as it substantially increases the number of applications for such a system. Another very attractive feature of this proposed approach is that it applies to diode arrays almost regardless of their operating wavelength because spatial filters and VBG retro-reflectors can be made over a wide wavelength range.

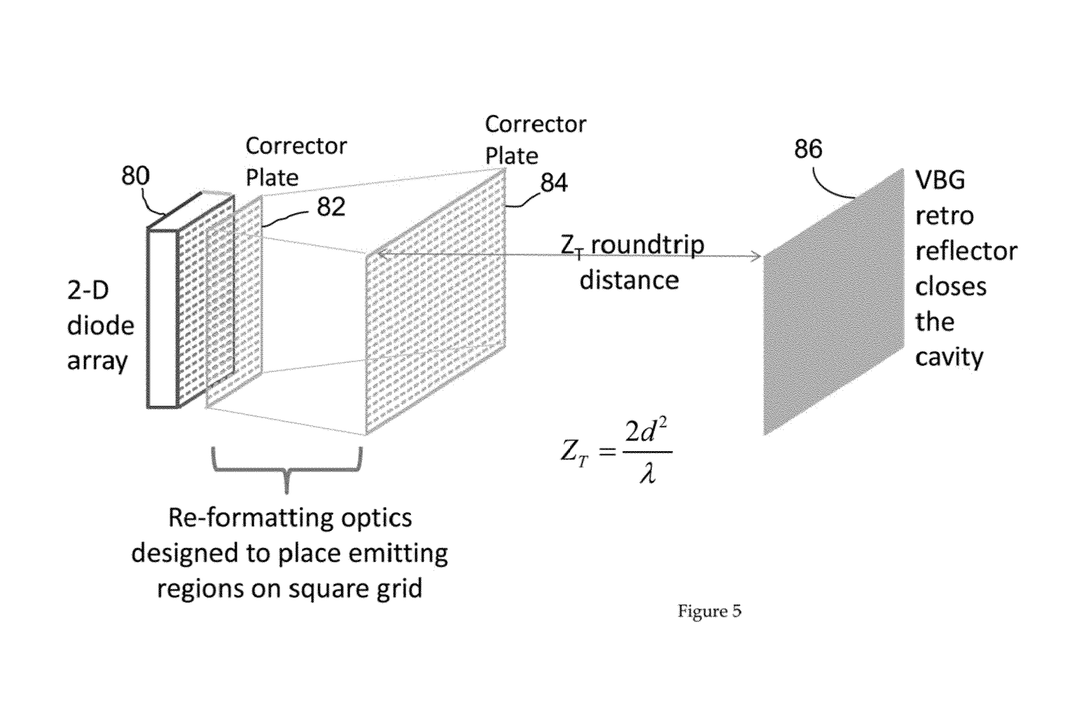

This invention applies to another family of resonators in which the spatial filter cavity described above is replaced by a Talbot cavity construction. Talbot cavity resonators are somewhat more complicated than the already discussed complex spatial filter resonators, but they have the advantage over the spatial filter cavities that there is no high irradiance intracavity spot (focal spot) required. Rather, instead of diffractively coupling through a tightly focused spot, the Talbot cavity enables diffractive coupling between multiple apertures that are placed on a regularly spaced grid, relying on the self-imaging properties of coherent arrays. FIG. 5 shows the structure in a schematic layout. Although Talbot cavity schemes have been pursued for phase locking laser diode arrays in the past, this invention is well distinguished from these previous attempts via the same two important aspects that distinguished this spatial filter approach from what others have demonstrated. First, this Talbot cavity invention incorporates the use of an advanced corrector optic that enables far field fast-axis pointing accuracy by correcting smile errors as already explained above. Second, this invention incorporates a single large aperture continuous vbg to supply spectral control in the feedback radiation that is used to establish diffractive coupling between the individual emitters in the array. So in effect this invention in this case is almost identical to the invention that uses a complex spatial filter with the difference being that rather than establishing diffractive coupling between the diode apertures that are to be phase locked with a complex spatial filter, here a Talbot cavity is used. A third distinguishing feature of this invention is the combination of the two correcting plates shown in FIG. 5, which together act in concert to bring all emitting apertures onto a regularly spaced spatial grid at the location of corrector plate 2 in the figure. Bringing all apertures onto a regularly spaced 2-D grid as shown is an important feature enabling the simple passive Talbot cavity scheme for phase locking the array to be employed. Beyond ensuring all apertures are registered to a regularly spaced spatial grid, the use of the two correcting plates gives us freedom in choosing the fill factor of the radiation at the output vbg of the system.

FIG. 5 is a schematic diagram of the present invention using a Talbot cavity for 2-D diode array phase locking. The output of the diode array 80 is conditioned by a FAC, SAC and possibly an AO integral (e.g., as shown in FIG. 1D) to the optics package on the diode array. If there is no AO included on the diode array optics package then the first corrector plate (82) serves the dual purpose of both correcting for the smile errors in the diode array, and directing the collimated radiation from the individual facets of the array to locations on a regularly spaced grid at the location of the second corrector plate (84). In the case where the diode array includes an integral AO in its optics package, corrector plate 82 only functions to direct the collimated radiation from the individual facets of the diode array to locations on a regularly spaced grid at the location of corrector plate 84. Whether the correction for smile error is done with an independent stand-alone AO as was the case in the spatial filter phase locking, or done by combining the AO function into corrector plate 82, the same technique is used for the correction, i.e., near field tilt errors in the diode radiation resulting from smile errors at the diode array are refractively corrected. Corrector plate 82 then splays out the diode radiation from the individual facets of the 2-D array such that at the location of corrector plate 84 the period in both the horizontal and vertical directions between light from the individual diode array emitters is the same, i.e., 2-D periodicity is established at corrector plate 84. Corrector plate 84 then redirects the individual pencil beams from the array emitters so that after corrector plate 84 all pencil beams are propagating parallel to each other and normal to the plane defined by corrector plate 84. In essence corrector plate 84 is an array of prismatic beam directors that refractively adjust the propagation direction of each beam such that after corrector plate 84 all beams propagate in the same direction. The Talbot cavity is then formed in the roundtrip free-space propagation of the diode light from corrector plate 84 to VBG 86 from which it is reflected, and then back to corrector plate 84. The Talbot cavity functions because at integer multiples of the Talbot distance the propagating field reconstructs itself in both amplitude and phase via free space propagation only if the original field exhibits the same periodicity as corrector plate 84. By placing the VBG mirror at one half of the Talbot distance from corrector plate 84 as shown in FIG. 5, so that the round trip distance from corrector plate 84 to VBG 86 and then back to corrector plate 84 is one Talbot distance, it is ensured that the lowest loss mode, and so the preferred mode, will be the one that corresponds to a phase locked array because other modes will experience higher loss at the periodic array that makes up corrector plate 84. As in the case of spatial filter phase locking, VBG 86 selectively retro reflects only a narrow spectrum. The roundtrip distance Z_{T} between corrector plate 84 and VBG 86 is set to be equal to 2d² divided by the wavelength λ, where d is the aperture to aperture spacing in corrector plate 84.

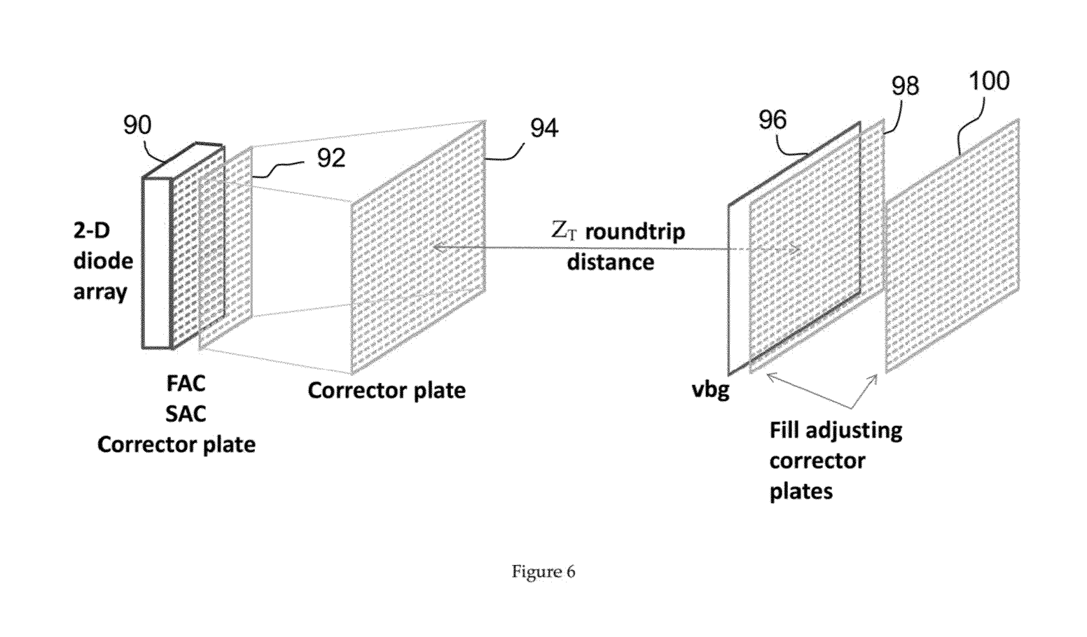

Small fill factors are driven by the desire to have high transverse mode discrimination, while large fill factors are driven by the desire to have high Strehl ratio output beams. For the first time, this invention gives us the freedom to meet both of these requirements simultaneously by adding another set of optical corrector plates after the VBG, as shown in FIG. 6, to condition the output radiation from the Talbot cavity. The figure shows a 2-D diode array 90, which can be optically conditioned as in FIG. 1D, or can be conditioned by a first corrector plate 92. Within the Talbot cavity the fill factor at corrector plate 94 can be kept small to optimize transverse mode discrimination while the fill factor after the cavity can be maximized after VBG 96 with correcting plates (98, 100) to maximize the fill at the output end of the plate pair, thereby maximizing the emitted Strehl ratio of the light.

Thus, FIG. 6 shows a Talbot cavity similar to that of FIG. 5, but with a follow on pair of corrector plates (98, 100) after the VBG reflector 96. The function of this follow on set of corrector plates is to maximize the fill factor of the phase locked output beams at the output plate and thereby maximize the Strehl ratio of the emitted radiation.

A final important aspect of the proposed structure shown in FIG. 6 is the ability to use the final adjusting plates to remap the phase of the individual apertures that comprise the phase locked beam. The cavity shown in FIG. 6 is indicated to have a roundtrip cavity distance equal to the Talbot distance, Z_{T}, given by

$${Z}_{T} = \frac{2 {d}^{2}}{λ} . \qquad ( 1 )$$

A round trip cavity distance of Z_{T} is advantageous as this cavity length gives large transverse mode discrimination, which is very desirable for high beam quality operation as already mentioned. But an undesirable feature of this cavity is that the lowest loss mode is the out-of-phase one in which there is phase change of π radians between adjacent emitters, at the location of the VBG. For high Strehl outputs the in-phase mode is most desirable as already discussed. The advantage of this invention here is that we can satisfy both requirements simultaneously, running the highest discrimination out-of-phase mode inside the cavity and then correcting the phase outside the cavity with the final adjusting plates to get back to an in-phase mode. Finally to give an idea of the cavity length scales we are talking about here, for a 1 mm aperture to aperture spacing, which is typical of this diode bars and bar stacking pitches, and 780 nm wavelength laser diode arrays, the Talbot distance is 256 cm giving an approximate cavity length for the system shown in FIG. 6 of 128 cm.

Finally, we note that the same technology approaches used above are applicable to arrays of other lasers such as for example, fiber lasers, or solid state lasers.

The foregoing description of the invention has been presented for purposes of illustration and description and is not intended to be exhaustive or to limit the invention to the precise form disclosed. Many modifications and variations are possible in light of the above teaching. The embodiments disclosed were meant only to explain the principles of the invention and its practical application to thereby enable others skilled in the art to best use the invention in various embodiments and with various modifications suited to the particular use contemplated. The scope of the invention is to be defined by the following claims.

We claim:

1. An apparatus, comprising:
an array of laser emitters for emitting a plurality of laser beams;
at least one fast-axis collimating lens positioned to collimate the fast axis of said plurality of laser beams to produce first collimated beams;
means for collimating the slow axis of said first collimated beams to produce second collimated beams;
means for correcting smile error in said second collimated beams to produce corrected beams;
a partial reflector operatively located to reflect each corrected beam of said corrected beams back into the respective laser emitter of said laser emitters from which said each corrected beam was emitted; and
a diffractive coupler located between said means for correcting smile errors and said partial reflector.

2. The apparatus of claim 1, wherein said array comprises a laser diode array having output facets from which said plurality of laser beams are emitted, wherein said output facets comprise a low reflectivity coatings.

3. The apparatus of claim 2, wherein said array comprises a 2-D laser diode array.

4. The apparatus of claim 1, wherein said array is selected from the group consisting of a solid state laser array and a fiber laser array.

5. The apparatus of claim 1, wherein said means for correcting smile error comprises an advanced optic (AO) configured to restore the pointing accuracy of said plurality of laser beams so that they propagate to said partial reflector and back into the respective laser emitter from which they were emitted.

6. The apparatus of claim 5, wherein said AO comprises a transparent substrate material, wherein said pointing accuracy is restored through refractive correction.

7. The apparatus of claim 1, wherein said partial reflector comprises a Bragg grating.

8. The apparatus of claim 7, wherein said Bragg grating comprises a shallow Bragg grating.

9. The apparatus of claim 7, wherein said Bragg grating comprises a volume Bragg grating.

10. The apparatus of claim 1, wherein said partial reflector is configured to limit the bandwidth of light reflected by said partial reflector to two tenths of a nanometer or less.

11. The apparatus of claim 7, wherein said Bragg grating is configured to limit the bandwidth of light reflected by said partial reflector to two tenths of a nanometer or less.

12. The apparatus of claim 7, wherein the pass band of said Bragg grating is less than the natural linewidth of said plurality of laser beams.

13. The apparatus of claim 1, wherein said partial reflector is a spectrally selective mirror.

14. The apparatus of claim 1, wherein said diffractive coupler is configured for promoting the intracavity diffractive coupling from laser emitter to laser emitter of said laser emitters.

15. The apparatus of claim 1, wherein said diffractive coupler comprises an intracavity spatial filter.

16. The apparatus of claim 15, wherein said intracavity spatial filter comprises a complex intracavity spatial filter.

17. The apparatus of claim 1, further comprising a first lens positioned for focusing said corrected beam onto said diffractive coupler to produce coupled beams, further comprising a second lens for collimating said coupled beams after they emerge from the diffractive coupler.

18. The apparatus of claim 1, wherein said diffractive coupler comprises an intracavity spatial filter, the apparatus further comprising a first lens for focusing said corrected beam onto said intracavity spatial filter to produce filtered beams, further comprising a second lens for collimating said filtered beams.

19. The apparatus of claim 18, wherein said intracavity spatial filter comprises an aperture having transmission at locations in the transform plane only where the irradiance is greater than a selected threshold value of the peak irradiance in that plane, wherein there is no transmission elsewhere.

20. The apparatus of claim 1, wherein the means for correcting smile error comprises an advanced optic, wherein said diffractive coupler comprises a Talbot cavity having a first corrector plate and a second corrector plate, wherein said second corrector plate is located such that the roundtrip difference Z_{T} between it and said partial reflector is set to be equal to (within 10%) 2d² divided by the wavelength λ, where d is the aperture to aperture spacing in said second corrector plate, wherein said first corrector plate is between said AO and said second corrector plate.

21. The apparatus of claim 20, wherein said first corrector plate comprises a first array of lenslets and said second corrector plate comprises a second array of lenslets.

22. The apparatus of claim 20, further comprising a third corrector plate located on the output side of said partial reflector, further comprising a fourth corrector plate on the output side of said third corrector plate and operatively located to set the fill at the output thereof to a desired size.

23. The apparatus of claim 1, wherein said diffractive coupler comprises a Talbot cavity having a first corrector plate and a second corrector plate located such that the roundtrip difference Z_{T} between the second corrector plate and said partial reflector is set to be equal to (within 10%) 2d² divided by the wavelength λ, where d is the aperture to aperture spacing in said second corrector plate, wherein said first corrector plate is between said slow-axis collimating lenses and said second corrector plate and wherein the means for correcting smile error comprises said first corrector plate.

24. The apparatus of claim 23, wherein said first corrector plate comprises a first array of lenslets and said second corrector plate comprises a second array of lenslets.

25. The apparatus of claim 23, further comprising a third corrector plate located on the output side of said partial reflector, further comprising a fourth corrector plate on the output side of said third corrector plate and operatively located to set the fill at the output thereof to a desired size.

26. The apparatus of claim 1, wherein said means for collimating the slow axis of said first collimated beams comprises an array of lenslets.

27. A method, comprising:
emitting a plurality of laser beams from an array of laser emitters;
collimating the fast axis of said plurality of laser beams to produce first collimated beams;
collimating the slow axis of said first collimated beams to produce second collimated beams;
correcting smile error in said second collimated beams to produce corrected beams;
diffractively coupling said corrected beams; and
reflecting a portion of each corrected beam of said corrected beams back into the respective laser emitter of said laser emitters from which said each corrected beam was emitted.

28. A method, comprising:
providing the apparatus of claim 1;
emitting a plurality of laser beams from said array of laser emitters for;
collimating, with at least one fast-axis collimating lens, the fast axis of said plurality of laser beams to produce first collimated beams;
collimating, with means for collimating, the slow axis of said first collimated beams to produce second collimated beams;
correcting, with means for correcting, smile error in said second collimated beams to produce corrected beams;
diffractively coupling, with a diffractive coupler, said corrected beams; and
reflecting, with a partial reflector, each corrected beam of said corrected beams back into the respective laser emitter of said laser emitters from which said each corrected beam was emitted.

29. The method of claim 28, wherein said array is selected from the group consisting of a laser diode array, a solid state laser array and a fiber laser array.

30. The method of claim 28, wherein said means for correcting smile error comprises an advanced optic (AO) configured to restore the pointing accuracy of said plurality of laser beams so that they propagate to said partial reflector and back into the respective laser emitter from which they were emitted.

31. The method of claim 28, wherein said partial reflector comprises a Bragg grating.

32. The method of claim 31, wherein said Bragg grating is configured to limit the bandwidth of light reflected by said partial reflector to two tenths of a nanometer or less.

33. The method of claim 28, wherein said diffractive coupler comprises an intracavity spatial filter.

34. The method of claim 28, wherein the means for correcting smile error comprises an advanced optic, wherein said diffractive coupler comprises a Talbot cavity having a first corrector plate and a second corrector plate, wherein said second corrector plate is located such that the roundtrip difference Z_{T} between it and said partial reflector is set to be equal to (within 10%) 2d² divided by the wavelength λ, where d is the aperture to aperture spacing in said second corrector plate, wherein said first corrector plate is between said AO and said second corrector plate.

35. The method of claim 34, further comprising a third corrector plate located on the output side of said partial reflector, further comprising a fourth corrector plate on the output side of said third corrector plate and operatively located to set the fill at the output thereof to a desired size.

36. The method of claim 28, wherein said diffractive coupler comprises a Talbot cavity having a first corrector plate and a second corrector plate located such that the roundtrip difference Z_{T} between the second corrector plate and said partial reflector is set to be equal to (within 10%) 2d² divided by the wavelength λ, where d is the aperture to aperture spacing in said second corrector plate, wherein said first corrector plate is between said slow-axis collimating lenses and said second corrector plate and wherein the means for correcting smile error comprises said first corrector plate.

37. The method of claim 36, further comprising a third corrector plate located on the output side of said partial reflector, further comprising a fourth corrector plate on the output side of said third corrector plate and operatively located to set the fill at the output thereof to a desired size.

38. The method of claim 28, wherein said means for collimating the slow axis of said first collimated beams comprises an array of lenslets.
